(19) United States
(12) Patent Application Publication
(10) Pub. No.: US 2009/0250107 A1
(43) Pub. Date: Oct. 8, 2009

(54) PHOTOVOLTAIC DEVICE

(75) Inventors: HAI-LIN SUN, Beijing (CN); KAI-LI JIANG, Beijing (CN); QUN-QING LI, Beijing (CN); SHOU-SHAN FAN, Beijing (CN)

Correspondence Address: PCE INDUSTRY, INC.;ATT. Steven Reiss, 288 SOUTH MAYO AVENUE, CITY OF INDUSTRY, CA, 91789, US

(73) Assignees: TSINGHUA UNIVERSITY, Beijing (CN); HON HAI PRECISION INDUSTRY CO., LTD., Tu-Cheng (TW)

(21) Appl. No.: 12/339,359

(22) Filed: Dec. 19, 2008

(30) Foreign Application Priority Data
Apr. 3, 2008 (CN) 200810066509.0

(51) Int. Cl. H01L 31/0216

(52) U.S. Cl. 136/256; 977/742

(57) ABSTRACT

A photovoltaic device includes a substrate, a first electrode and a carbon nanotube structure. The substrate has a front surface and a rear surface. The carbon nanotube structure is disposed on the front surface of the substrate. The first electrode is disposed on the rear surface of the substrate.

### BACKGROUND

1. Technical Field

The invention relates to energy conversion devices, and particularly to a photovoltaic device.

2. Description of Related Art

Currently, solar energy is considered a renewable and clean energy source, and can also be used as an alternative source of energy other than fossil fuel. Solar energy is generally produced by photovoltaic cells, also known as solar cells. The photovoltaic cell or the solar cell is a device that converts light into electrical energy using the photoelectric effect.

Generally, the solar cell includes a large-area p-n junction made from silicon. Silicon employed in the solar cell can be single crystal silicon or polycrystalline silicon. Solar cells based on single crystal silicon are efficient at energy conversion. However, much electric power is needed to produce single crystal silicon, which is expensive. Therefore, there is an increasing demand for low-cost solar cells based on polycrystalline silicon.

Referring to FIG. 6, a conventional solar cell 30 according to the prior art generally includes a silicon substrate 34, a doped silicon layer 36, a front electrode 38, and a rear electrode 32. The silicon substrate 34 is made of polycrystalline silicon. The doped silicon layer 36 is formed in intimate contact with the silicon substrate 34 to form a p-n junction. The front electrode 38 is disposed on and electrically connected to the doped silicon layer 36. The rear electrode 32 is disposed on and electrically connected to, e.g. via ohmic contact, the silicon substrate 34. In use, the electrodes 32, 38 are connected to an external load. Current will be generated and flow in one direction across the p-n junction by the action of the electric field if sunlight strikes the solar cell 30.

However, during the process of growing polycrystalline silicon, defects, such as dangling bonds, will occur at grain-boundaries of the polycrystalline silicon. Such defects form sites where mobile carriers will be captured, disrupting the flow of electrons. In addition, the recombination of electron-hole pairs will decrease due to such defects. In sum, the mobility of electrons and the efficiency of energy conversion are decreased.

Fabrication of the solar cell 30 is usually done using high temperature to produce the doped silicon layer 36. Furthermore, the front electrode 38, which is made of metal and fabricated by screen-printing, is appeared to have a structure with large area. Consequentially, much of the incoming light will be blocked from penetrating into the solar cell 30 due to the wide area of the front electrode 38, causing lower energy conversion efficiency.

What is needed, therefore, is a photovoltaic device that overcomes the above problems.

### BRIEF DESCRIPTION OF THE DRAWINGS

The components in the drawing are not necessarily drawn to scale, the emphasis instead being placed upon clearly illustrating the principles of the present invention.

FIG. 1 is a schematic lateral view showing a photovoltaic device in accordance with an exemplary embodiment.

FIG. 2 is a schematic vertical view showing the photovoltaic device of FIG. 1.

FIG. 3 is a schematic enlarged view showing a portion of a carbon nanotube structure of the photovoltaic device of FIG. 1.

FIG. 4 is a schematic enlarged view showing a portion of a substrate of the photovoltaic device of FIG. 1.

FIG. 5 is a schematic enlarged view showing portions of the substrate and the carbon nanotube structure of the photovoltaic device of FIG. 1.

FIG. 6 is a schematic view of a conventional solar cell according to the prior art.

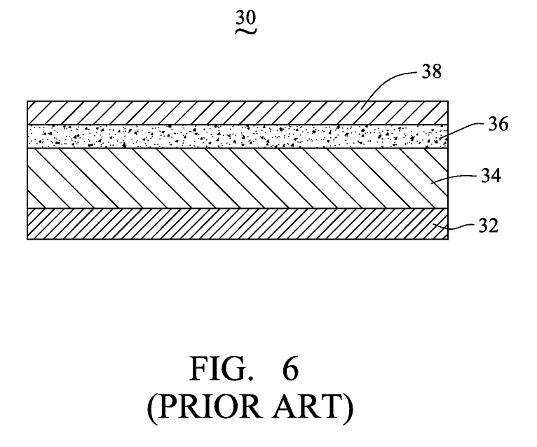

Corresponding reference characters indicate corresponding parts throughout the drawings. The exemplifications set out herein illustrate at least one embodiment of the present photovoltaic device, in one form, and such exemplifications are not to be construed as limiting the scope of the disclosure in any manner.

### DETAILED DESCRIPTION OF THE EMBODIMENT

Reference will now be made to the drawings to describe embodiments of the present photovoltaic device in detail.

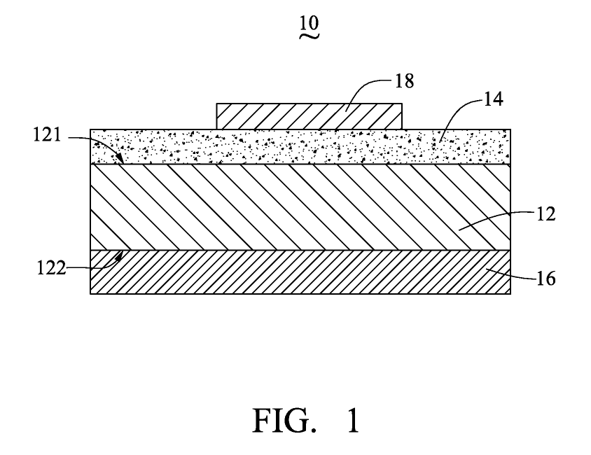

Referring to FIG. 1, a photovoltaic device 10 according to an exemplary embodiment, is shown. The photovoltaic device 10 includes a substrate 12, a carbon nanotube (CNT) structure 14, and a first electrode 16.

The substrate 12 is made of polycrystalline silicon. Particularly, the polycrystalline silicon is n-type polycrystalline silicon. The substrate 12 has a front surface 121 and a rear surface 122, as shown in FIG. 1. In addition, a thickness of the substrate 12 is in an approximate range from 200 μm to 300 μm.

The CNT structure 14 is disposed on the front surface 121 of the substrate 12. Particularly, the CNT structure 14 is formed in intimate contact with the substrate 12, the point of contact forming a heterostructure. The CNT structure 14 is configured to absorb light and the light is converted to electrical energy via the heterostructure under the photovoltaic effect.

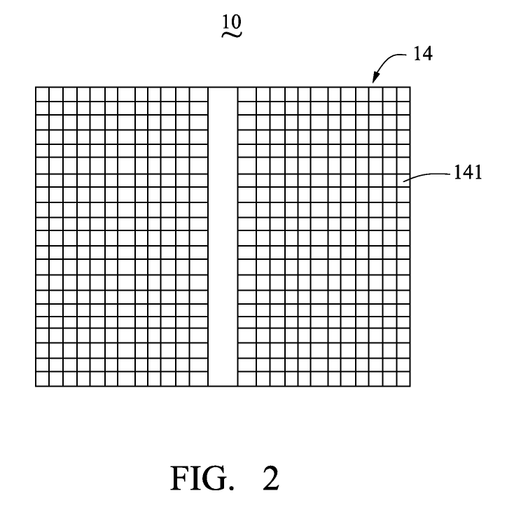

Referring to FIG. 2, the CNT structure 14 includes at least one CNT layer 141, which can include a plurality of uniformly distributed and/or disordered CNTs. In the exemplary embodiment, the CNT layer 141 can be an ordered CNT layer, as shown in FIG. 2, or a disordered CNT layer. That is, the CNTs of the CNT layer 141 can be arranged orderly or disorderly/randomly.

In the ordered CNT layer 141, the CNTs are arranged along and parallel to a surface of the CNT layer 141. In addition, the CNTs of the ordered CNT layer 141 are oriented along one direction. Alternatively, the CNTs layers 141 of the CNT structure 14 can be oriented along different directions, e.g. two directions perpendicular to each other. In a disordered CNT layer 141, CNTs entangle with each other or are arranged in an isotropic fashion.

In the present embodiment, the CNTs of the CNT structure 14 can be selected from a group consisting of single-walled carbon nanotubes (SWCNTs), double-walled carbon nanotubes, multi-walled carbon nanotubes (MWCNTs), and combinations thereof. In such case, when the SWCNTs are employed in the CNT structure 14, a diameter of each of the SWCNTs is in an approximate range from 0.5 nm to 50 nm. Alternatively, when the MWCNTs are employed in the CNT structure 14, a diameter of each of the MWCNTs is in an approximate range from 1.0 nm to 50 nm. In the exemplary embodiment, the CNT structure 14 can be directly adhered on the front surface 121 of the substrate 12 due to the CNTs having high purity and large surface areas.

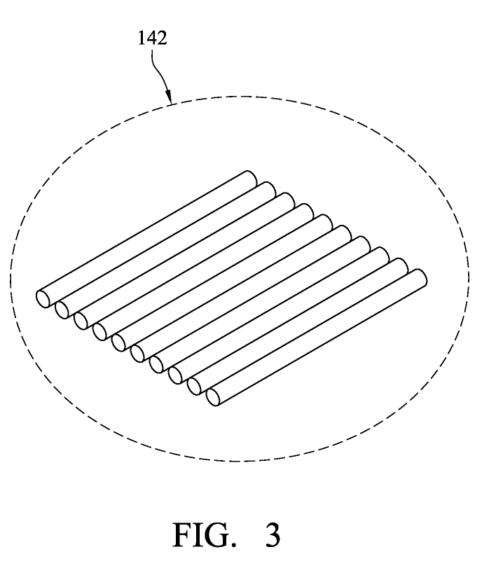

Alternatively, the CNT layer 141 can include at least one CNT film. The CNT film can be fabricated by being drawn from a CNT array. In the exemplary embodiment, the CNT array is formed on a 4-inch silicon by vapor deposition. The CNT film includes a plurality of successively oriented CNT segments 142 joined end-to-end by van der Waals attractive force, as shown in FIG. 3. Each CNT segment 142 includes a plurality of CNTs substantially parallel to each other and of approximately the same length. Adjacent CNTs are also attracted by van der Waals attractive force. Due to substantially parallel-arranged and uniformly distribution of CNTs, the photovoltaic device 10 has uniform electric resistance, improved conductivity and high energy conversion efficiency. In the exemplary embodiment, the CNT film has a width in an approximate range from 0.01 cm to 10.00 cm and a thickness in an approximate range from 10 nm to 100 nm. In practice, the CNT segments 142 can vary in width, thickness, uniformity, and shape.

In the exemplary embodiment, each CNT layer 141 includes a plurality of successively stacked CNT films. The parallel-aligned CNTs of any two adjacent CNT films intersect an angle, for example, in a range from 0 degrees to 90 degrees. The number of stacked CNT films can be chosen according to the practical requirements, forming different thickness of the CNT layer 141. Also, the number CNT layers can be chosen according to the practical requirements, forming different thickness of the CNT structure 14.

However, the CNT structure 14 is not limited to what is mentioned above. The CNT layer 141 can include a plurality of CNT yarns, which are substantially parallel to one another, to form the CNT structure 14. A CNT yarn is a CNT film with smaller width. As mentioned above, the CNT structure 14 can have multiple stacked CNT layers each having CNT yarns. In such case, the orientation of the CNT yarns of any two adjacent CNT layers is set at an angle in an approximate range from 0 degrees to 90 degrees.

In other embodiments, the CNT structure 14 also can consist of at least one CNT film layer 141 and at least one CNT yarn layer 141. The CNT yarn layer comprises of two or more yarns that are parallel to each other. The CNT yarn layer can be disposed on the CNT film layer in such a way that the CNTs in the film and the yarn are substantially parallel to one another. If the CNT structure 14 has a plurality of CNT films layers and CNT yarns layers, each CNT film layer and CNT yarn layers can be alternately stacked. In other embodiments, the CNTs in the adjacent CNT film and yarn layers are not parallel.

Alternatively, the CNT structure 14 also can be formed by coating a composited material of a mixture of CNT powders and metal on the substrate 12.

The first electrode 16 is disposed on and contacts with the rear surface 122 of the substrate 12, as shown in FIG. 1. The first electrode 16 can be made of aluminum (Al), magnesium (Mg) or silver (Ag). In addition, the first electrode 16 has a thickness in an approximate range from 10 μm to 300 μm. The photovoltaic device 10 of the exemplary embodiment can further include a second electrode 18 disposed, for example, on the CNT structure 14. Alternatively, the second electrode 18 also can be disposed on and contact with the rear surface 122 of the substrate 12 (not shown). The second electrode 18 can be made of conductive material, such as silver, gold (Au), or CNTs. The second electrode 18 can vary in thickness and shape.

In use, light strikes the front surface 121 of the photovoltaic device 10, radiated photos are absorbed by the CNT structure 14 and create a lot of mobile carriers (hole-electron pairs) at the heterostructure formed by the interface of the substrate 12 and the CNT structure 14. Then, the hole-electron pairs are separated to form a plurality of holes and electrons by the electrostatic potential energy. The holes move across the substrate 12 to the first electrode 16 and are collected by the first electrode 16. The electrons are transmitted and collected by the CNT structure 14. The electrons can further be collected by the second electrode 18. As a result, an electric current goes through an electrical circuit outside of the photovoltaic device 10.

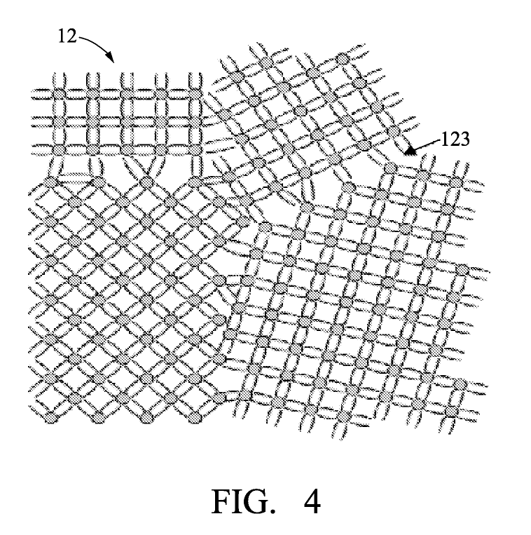

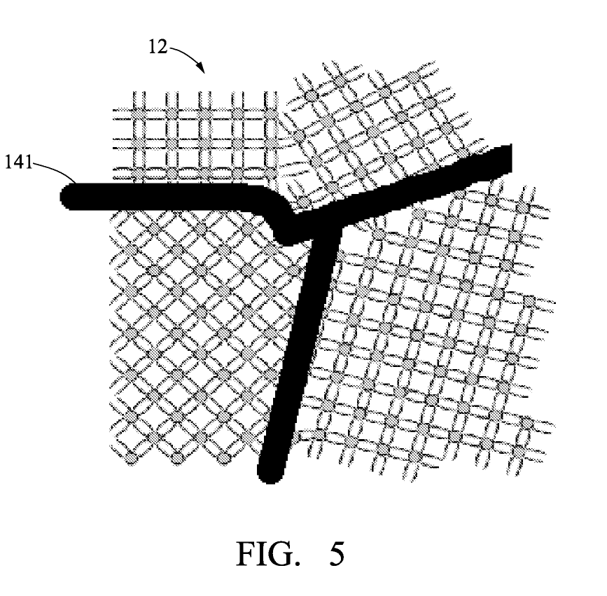

Referring to FIG. 4 and FIG. 5, because the substrate 12 has unsaturated dangling bonds at grain-boundaries 123 thereof, the CNT structure 14 easily adheres to the front surface 121 of the substrate 12 through a reaction of the CNT structure 14 and the unsaturated dangling bonds. The use of an adhesive is not required. In addition, the generated mobile carriers will be prevented from being captured by the unsaturated dangling bonds. As a result, the energy conversion efficiency and the mobility of electrons will be improved.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A photovoltaic device, comprising:
a substrate having a front surface and a rear surface;
a carbon nanotube structure disposed on the front surface of the substrate; and
a first electrode disposed on the rear surface of the substrate.

2. The photovoltaic device as claimed in claim 1, wherein the substrate is made of polycrystalline silicon.

3. The photovoltaic device as claimed in claim 1, wherein the substrate comprises n-type polycrystalline silicon.

4. The photovoltaic device as claimed in claim 1, wherein a thickness of the substrate is in a range from 200 μm to 300 μm.

5. The photovoltaic device as claimed in claim 1, wherein the carbon nanotube structure comprises at least one carbon nanotube layer.

6. The photovoltaic device as claimed in claim 5, wherein the at least one carbon nanotube layer comprises a plurality of the carbon nanotubes, which are arranged orderly or disorderly.

7. The photovoltaic device as claimed in claim 5, wherein the at least one carbon nanotube layer comprises at least one carbon nanotube film; the at least one carbon nanotube film comprises of a plurality of successively oriented carbon nanotube segments joined end-to-end by van der Waals attractive force.

8. The photovoltaic device as claimed in claim 7, wherein each carbon nanotube segments comprises a plurality of carbon nanotubes substantially parallel to each other.

9. The photovoltaic device as claimed in claim 8, wherein the at least one carbon nanotube layer comprises a plurality of successively stacked carbon nanotube films.

10. The photovoltaic device as claimed in claim 9, wherein the carbon nanotubes of the adjacent carbon nanotube films intersect an angle in a range from 0 degrees to 90 degrees.

11. The photovoltaic device as claimed in claim 5, wherein the at least one carbon nanotube layer comprises a plurality of carbon nanotube yarns, which are substantially parallel to one another.

12. The photovoltaic device as claimed in claim 11, wherein the carbon nanotube structure comprises a plurality of stacked carbon nanotube layers, and the orientation of the carbon nanotube yarns of adjacent carbon nanotube layers are set at an angle that ranges from 0 degrees to 90 degrees.

13. The photovoltaic device as claimed in claim 1, wherein the carbon nanotube structure comprises at least two carbon nanotube layers; and
wherein one carbon nanotube layer comprises of one or more carbon nanotube films and one carbon nanotube layer comprises of a plurality of carbon nanotube yarns.

14. The photovoltaic device as claimed in claim 1, wherein the carbon nanotube structure comprises a plurality of carbon nanotube film layers and a plurality of carbon nanotube yarn layers, and each carbon nanotube film layer is adjacent to a carbon nanotube yarn layer.

15. The photovoltaic device as claimed in claim 1, wherein the first electrode is made of aluminum, magnesium, or silver.

16. The photovoltaic device as claimed in claim 1, wherein a thickness of the first electrode is in an approximate range from 10 μm to 300 μm.

17. The photovoltaic device as claimed in claim 1, further comprises a second electrode disposed on the carbon nanotube structure.
